(19) United States
(12) Patent Application Publication
(10) Pub. No.: US 2014/0111919 A1
(43) Pub. Date: Apr. 24, 2014

(54) METHOD FOR MANUFACTURING ELECTRONIC DEVICE, BONDING DEVICE FOR ELECTRONIC COMPONENT CONTAINER, ELECTRONIC APPARATUS, AND APPARATUS FOR MOVING OBJECT

(71) Applicant: Seiko Epson Corporation, Tokyo (JP)

(72) Inventors: Hideo Miyasaka, Okaya (JP); Kazuhisa Hashimoto, Ina (JP)

(73) Assignee: Seiko Epson Corporation, Tokyo (JP)

(21) Appl. No.: 14/049,283

(22) Filed: Oct. 9, 2013

(30) Foreign Application Priority Data
Oct. 23, 2012 (JP) 2012-233498

(51) Int. Cl. H05K 13/04; H05K 5/03

(52) U.S. Cl. CPC H05K 13/046; H05K 5/03
USPC 361/679.01; 156/273.7; 156/379.8

(57) ABSTRACT

A bonding method of a container having a base substrate, and a lid member adapted to form a space with the base substrate includes: providing the base substrate and the lid member, arranging the lid member so as to overlap a bonding area of the base substrate, making a pressing member have contact with an exterior surface of an area of the lid member surrounded by the bonding area, and performing bonding by irradiating the lid member with an energy beam in the state of making the pressing member have contact with the lid member.

### BACKGROUND

1. Technical Field

The present invention relates to a method of manufacturing an electronic device, a bonding device for an electronic component container, an electronic apparatus, and an apparatus for a moving object.

2. Related Art

As a surface mount electronic component having an electronic element airtightly encapsulated in a container in order to suppress the aging deterioration of the electronic element to thereby keep the stability, there can be cited a piezoelectric device, a semiconductor device, and so on. In airtightly encapsulating the electronic element in the container, there is commonly used a method of disposing the electronic element inside a recessed portion of a base substrate (the container main body) formed of ceramic provided with the recessed portion, achieving the electrical conduction between the electronic element and the base substrate side wiring line using an electrically-conductive member, and then welding a sealing section (a metalization layer) formed on the periphery of the recessed portion of the base substrate and a lid member made of metal to each other using seam welding (resistance welding), an energy beam (e.g., a laser beam, an electron beam), ultrasonic wave, and so on to thereby bond the sealing section and the lid to each other.

JP-A-2001-274649 (Document 1) discloses an airtight sealing method of a quartz crystal vibratory device. The surface mount quartz crystal vibratory device is provided with a base substrate (a container main body) having a recessed portion, a quartz crystal vibrator element to be housed in the recessed portion of the base substrate, and a lid member to be bonded to the periphery of the recessed portion of the base substrate. The base substrate and the lid member constitute the container.

On the periphery of the base substrate, there is formed a sealing section (a metalization layer) having a ring-like shape. The sealing section has a configuration having a tungsten metalization layer, a nickel plated layer, a gold plated layer, and so on stacked in sequence from the lower layer. Further, element mounting pads are formed inside the recessed portion of the base substrate, and the element mounting pads are electrically connected to mounting terminals formed on the exterior bottom surface of the base substrate via through holes. The quartz crystal vibrator element is cantilevered by the element mounting pads via electrically-conductive adhesive.

Further, the lid member has kovar as a lid member base material, and a brazing material layer corresponding to the sealing section is formed on one surface of the base material. The brazing material layer is made of silver solder, and has a configuration of forming a thin-wall region only in an area corresponding to a non-welded region described later.

In an airtight sealing process, first, welding is partially performed using a parallel seam welder so that the non-welded region remains in a bonding area having a ring-like shape between the base substrate and the lid member. In performing the partial welding, the welder is controlled so that the non-welded region corresponds to the thin-wall region of the silver solder provided to the lid member in advance. Subsequently, the container housing the quartz crystal vibrator element is housed in a vacuum chamber provided with a spot welder, and then the chamber is exhausted to vacuum to thereby remove the gas in the container via a gap formed in the non-welded region. The non-welded region is spot-welded in this state to thereby complete the airtight seal, and the quartz crystal vibratory device is completed after electrical and mechanical inspections.

However, the parallel seam welder used in the airtight sealing process in Document 1 is a device for performing welding with two seam rollers running in parallel with each other, and there is a problem that it is difficult to miniaturize the seam rollers so small as to be able to be used for sealing an electronic component container as small as several millimeters on a side.

It should be noted that the energy beam bonding method such as the electron beam welding method or the laser bonding method can be used for sealing the small-sized electronic component container of several millimeters on a side. However, in these welding methods, since the welding target and the welding (bonding) source such as the electron beam or the laser beam are in a noncontact state when performing the welding, it is necessary to hold the lid member with a holding jig in order to prevent the lid member from being shifted during the welding after disposing the lid member so as to surround the electronic element on the base substrate. However, in reality, due to the tilt of the holding jig and the variation of the flatness of the lid member, it becomes difficult to make the lid member evenly adhere to the entire surface of the sealing section (the bonding area) of the base substrate, and in order to compensate this problem, combination use with the seam welding process becomes necessary. Therefore, there is a problem that the sealing cost increases due to increase in man-hour for sealing and the facility cost.

### SUMMARY

An advantage of some aspects of the invention is to provide a bonding method for a small-sized electronic component container, a laser bonding device, an electronic device manufactured using the bonding method or the bonding device, and an electronic apparatus and an apparatus for a moving object each equipped with the electronic device.

The invention can be implemented as the following forms or application examples.

### APPLICATION EXAMPLE 1

This application example is directed to a method of manufacturing an electronic device including: providing an electronic component, a lid member, a base substrate having a bonding area, and a pressing member, arranging the electronic component on the base substrate, arranging the lid member on the base substrate so as to overlap the bonding area of the base substrate, making the pressing member have contact with an area of the lid member surrounded by the bonding area in a plan view in a direction in which the base substrate and the lid member overlap each other, and bonding the base substrate and the lid member to each other by irradiating the lid member with an energy beam in a state of making the pressing member have contact with the lid member.

According to this method of manufacturing an electronic device, since the bonding is performed by arranging the base substrate mounted with an electronic component and the lid member so that the bonding area of the lid member overlaps the bonding area (sealing section) of the base substrate, and then irradiating the lid member with the energy beam (e.g., a laser beam) in the state of making the pressing member have contact with the exterior surface of the area of the lid member surrounded by the bonding area, namely in the state in which the bonding area of the base substrate and the bonding area of the lid member adhere to each other, there is an advantage that the yield of the electronic device with sufficient airtightness is dramatically improved.

### APPLICATION EXAMPLE 2

This application example is directed to the method of manufacturing an electronic device according to Application Example 1, wherein a part of the bonding area is bonded in the bonding of the base substrate and the lid member, and the method further includes detaching the pressing member from the lid member after the bonding of the base substrate and the lid member, and bonding a remaining area of the bonding area.

According to this method of manufacturing an electronic device, since the method goes through a partial bonding process of arranging the base substrate mounted with an electronic component and the lid member so that the bonding area of the lid member overlaps the bonding area (sealing section) of the base substrate, and then irradiating a part of the lid member with the energy beam (e.g., a laser beam) to thereby bonding the part of the lid member in the state of making the pressing member have contact with the exterior surface of the area of the lid member surrounded by the bonding area of the lid member, namely in the state in which the bonding area of the base substrate and the bonding area of the lid member adhere to each other throughout the entire surface due to the pressure by the pressing member, and then performs a full bonding process of releasing the pressing member and then bonding the non-bonded region, there is an advantage that the yield of the electronic device with sufficient airtightness is dramatically improved.

### APPLICATION EXAMPLE 3

This application example is directed to the method of manufacturing an electronic device according to Application Example 2, wherein seam welding is used in the bonding of a remaining area.

According to this method of manufacturing an electronic device, since the base substrate mounted with an electronic component and the lid member are arranged so that the bonding area of the lid member overlaps the bonding area (sealing section) of the base substrate, and then the energy beam (e.g., laser) bonding is performed on a part of the lid member in the state of making the pressing member have contact with the exterior surface of the area of the lid member surrounded by the bonding area, namely in the state in which the bonding area of the base substrate and the bonding area of the lid member adhere to each other, then the pressure by the pressing member is released, and then a full welding process of seam-welding the non-welded region is performed, there is an advantage that the yield of the electronic device with sufficient airtightness is dramatically improved.

### APPLICATION EXAMPLE 4

This application example is directed to a bonding device for an electronic component container adapted to bond a base substrate and a lid member to each other to assemble an electronic component container, including a pressing member adapted to fix the lid member to the base substrate, and an energy beam irradiation device adapted to irradiate the lid member with an energy beam to bond the base substrate and the lid member to each other.

According to this configuration, since the pressing member having contact with the exterior surface of the area of the lid member, which is arranged in the bonding area (the sealing section) of the base substrate, surrounded by the bonding area, and the energy beam irradiation device adapted to irradiate the lid member with the energy beam to thereby bond the bonding area of the lid member are provided, there is an advantage that the airtightness of the electronic component container is dramatically improved by going through this bonding process.

### APPLICATION EXAMPLE 5

This application example is directed to the bonding device for an electronic component container according to Application Example 4, wherein the pressing member includes a suction mechanism adapted to suck and transport the lid member.

According to this configuration, since the pressing member is provided with the suction mechanism for sucking the lid member, and the lid member can accurately arranged in the bonding area of the base substrate, there is an advantage that the airtightness of the electronic component container can dramatically be improved.

### APPLICATION EXAMPLE 6

This application example is directed to the bonding device for an electronic component container according to Application Example 4 or 5, wherein the pressing member includes a mechanism adapted to discharge a gas, and a mechanism adapted to suction a gas.

According to this configuration, since the gas discharge mechanism adapted to discharge an inert gas or the like to the bonding region between the base substrate and the lid member is provided, oxidization of a metal part is prevented, which is advantageous to cost reduction.

### APPLICATION EXAMPLE 7

This application example is directed to an electronic device manufactured by a method including: providing an electronic component, a lid member, a base substrate having a bonding area, and a pressing member, arranging the electronic component on the base substrate, arranging the lid member on the base substrate so as to overlap the bonding area of the base substrate, making the pressing member have contact with an area of the lid member surrounded by the bonding area in a plan view in a direction in which the base substrate and the lid member overlap each other, and bonding the base substrate and the lid member to each other by irradiating the lid member with an energy beam in a state of making the pressing member have contact with the lid member.

According to this configuration, there is an advantage that an electronic device good in frequency accuracy, frequency-temperature characteristic, and aging characteristic can be obtained.

### APPLICATION EXAMPLE 8

This application example is directed to an electronic apparatus including the electronic device according to Application Example 7.

According to this configuration, since the electronic apparatus is configured using an electronic device good in frequency accuracy, frequency-temperature characteristic, and aging characteristic, there is an advantage that an electronic apparatus stable in frequency for a long period of time is obtained.

### APPLICATION EXAMPLE 9

This application example is directed to an apparatus for a moving object including the electronic device according to Application Example 7.

According to this configuration, since the apparatus for a moving object is configured using the electronic device small in size, and good in output stability and aging characteristic, there is an advantage of achieving downsizing of the apparatus for a moving object, and obtaining the apparatus for a moving object stable in operation for a long period of time.

### BRIEF DESCRIPTION OF THE DRAWINGS

The invention will be described with reference to the accompanying drawings, wherein like numbers reference like elements.

FIG. 1A is a schematic vertical cross-sectional view showing a structure of a bonding jig used for a bonding method of an electronic component container according to an embodiment of the invention, and FIG. 1B is a partially enlarged cross-sectional view of the bonding jig.

FIG. 2A is a perspective view of the bonding jig viewed from below, and FIG. 2B is a perspective view of the bonding jig sucking a lid member viewed from below.

FIG. 3 is a schematic block diagram showing a configuration of an energy beam bonding device.

FIG. 4 is a partially enlarged vertical cross-sectional view of a container for explaining the energy beam bonding method.

FIG. 5 is a vertical cross-sectional view of an electronic device manufactured using the bonding method according to an embodiment of the invention.

FIG. 6A is a vertical cross-sectional view of a piezoelectric device as an example of the electronic device according to an embodiment of the invention, and FIG. 6B is a vertical cross-sectional view of another piezoelectric device.

FIG. 7 is a flowchart showing a manufacturing procedure of the electronic device.

FIG. 8A is a plan view showing a configuration of a gyro sensor, FIG. 8B is a vertical cross-sectional view of the gyro sensor, and FIG. 8C is a schematic view for explaining an operation.

FIG. 9 is a schematic block diagram of an electronic apparatus.

FIG. 10 is an explanatory diagram of an apparatus for a moving object.

### DESCRIPTION OF AN EXEMPLARY EMBODIMENT

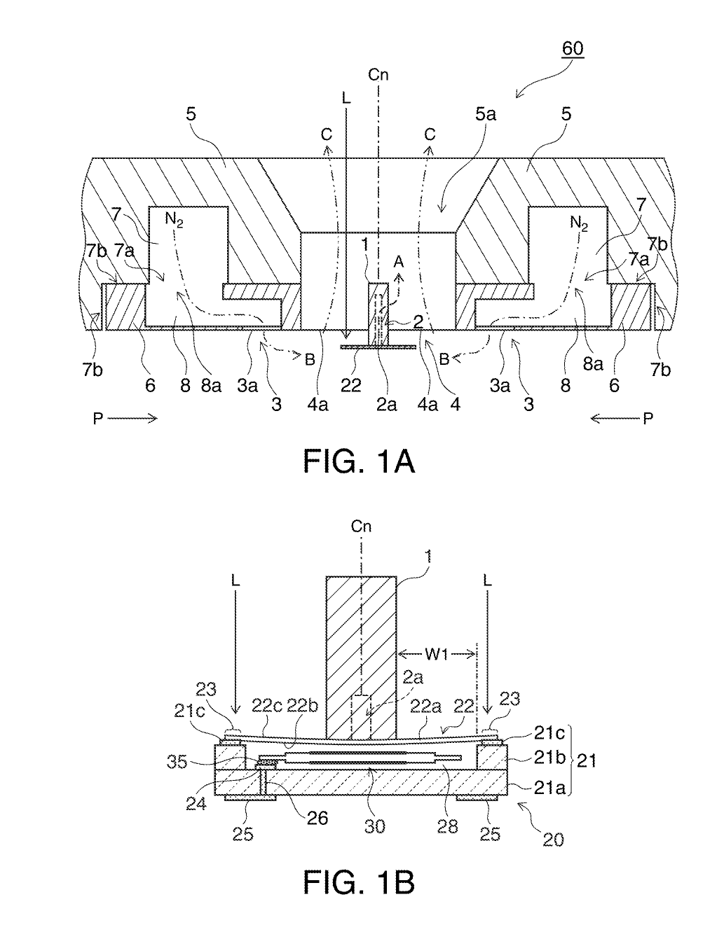

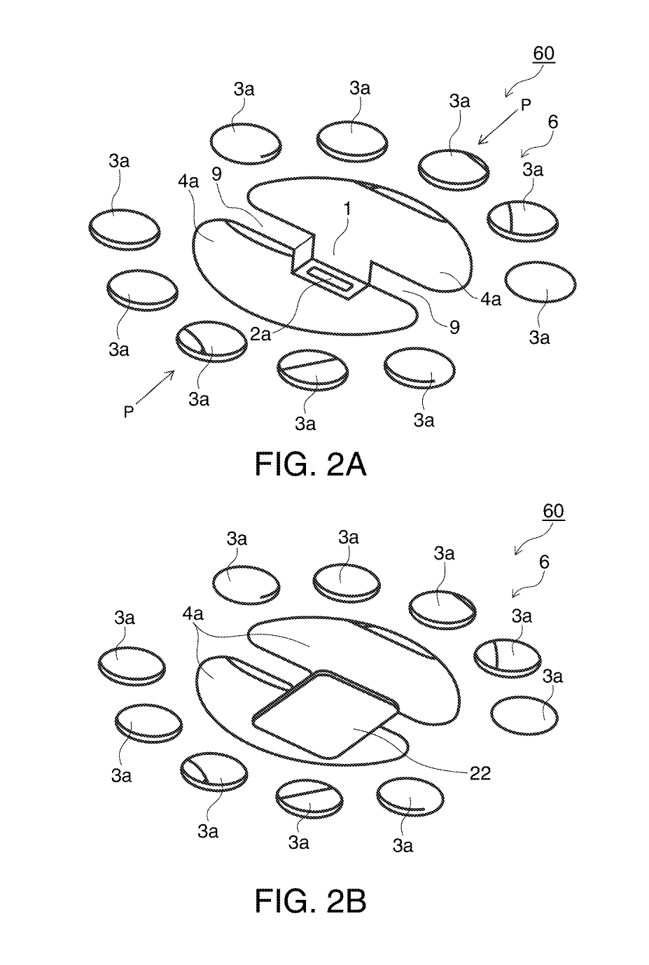

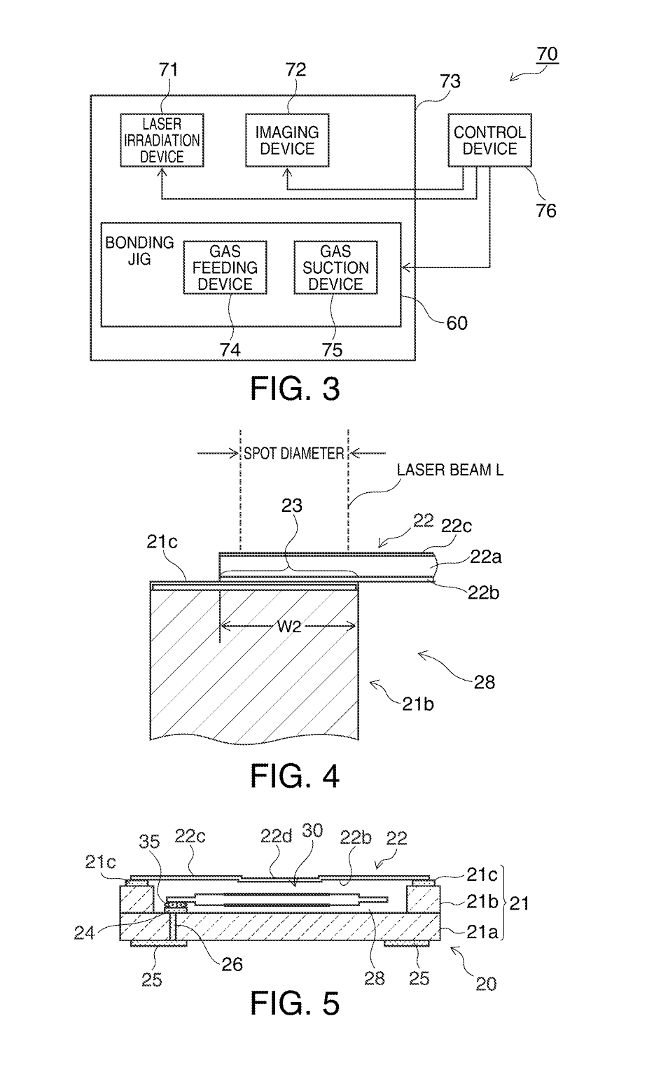

An embodiment of the invention will hereinafter be explained in detail with reference to the accompanying drawings. FIG. 1A is a schematic vertical cross-sectional view showing a configuration of a bonding jig 60 attached to an energy beam bonding device according to an embodiment of the invention, and FIG. 1B is a vertical cross-sectional view showing a part of the bonding jig 60 in an enlarged manner in a state in which a bonding area of a lid member 22 is disposed so as to overlap a sealing section 21c (a bonding area 23) of a base substrate 21, and an inside upper surface of the lid member is pressed by a pressing member 1. FIG. 2A is a perspective view of the bonding jig 60 viewed from below, and FIG. 2B is a perspective view of a state, in which the lid member 22 is sucked by a suction hole 2a provided to a bottom section of the pressing member 1, viewed from below the bonding jig 60. FIG. 3 is a schematic block diagram showing a configuration of an energy beam bonding device 70.

The energy beam bonding device 70 is roughly provided with an energy beam (e.g., a laser beam, an electron beam) irradiation device 71, an imaging device 72 for recognizing an object, the bonding jig 60, a gas feeding device 74, a plurality of gas suction device 75, a control device 76 for overall control, and a chamber 73 for housing these devices.

The energy beam irradiation device 71 is roughly provided with a laser generator for generating, for example, a laser beam L, a lens system for regulating the spot diameter of the laser beam L, and a mechanism for moving the spot position of the laser beam using a signal of the control device based on an object recognition signal from the imaging device 72.

The bonding jig 60 is roughly provided with the pushing member 1 provided with the suction hole 2a for sucking the lid member 22, a plurality of gas discharge holes 3a for discharging an inert gas such as a nitrogen gas (N₂), and fume suction holes 4a for suctioning fumes (metal droplets) flying in all directions when the metal of the lid member 22 is melted due to the energy beam L.

The bonding jig 60 is roughly provided with an upper plate 5 and a lower plate 6 shown in FIG. 1A, and has a structure of connecting the lower plate 6 to the bottom portion of the upper plate 5. The upper plate 5 has, for example, a cylindrical outer shape, and is provided with a hole 5a having a cylindrical shape in the lower part and an inverted conical shape in the upper part formed at a central portion of the circular bottom surface. Further, the bottom surface of the upper plate 5 is provided with a hollow section 7 having a ring-like shape, which is concentric with the hole 5a, formed on the outer circumferential side of the hole 5a, and the bottom portion of the hollow section 7 forms an opening section 7a having a ring-like shape. In other words, the cylindrical upper plate 5 is provided with the hole 5a penetrating along the center line Cn thereof, and a hollow section 7 as a ring-like groove disposed coaxially on the outer circumferential side of the hole 5a. Further, the bottom portion of the upper plate 5 is cut annularly with a larger diameter than the outer diameter of the hollow section 7 centered on the center line Cn as indicated by the reference symbol 7b in FIG. 1A.

The lower plate 6 is fitted in the cut section 7b to thereby be fixed. The lower plate 6 is provided with a continuous hole 8 having a ring-like shape formed through the lower plate 6, and the upper part of the continuous hole 8 communicates with the opening section 7a of the hollow section 7.

The lower plate 6 is an annular body (a hollow cylindrical body) to be fitted in the cut section 7b of the upper plate 5, and in the state of being assembled to the upper plate 5, the center line of the lower plate 6 coincides with the center (Cn) of the upper plate 5, and the continuous hole 8 communicates with the hollow section 7.

A projection section 1 (the pressing member) having a rectangular solid shape is disposed so as to project at the central portion of the bottom surface of the lower plate 6. As shown in FIG. 2A, connection sections 9 (each part of the bottom of the lower plate) with a narrow width extend respectively from a pair of wall surfaces of the projection section 1 opposed to each other, and the fume suction holes 4a are respectively opened in the bottom of the lower plate along the other pair of side walls opposed to each other.

An imaginary center of the two fume suction holes 4a corresponds to the center line Cn. The lower plate 6 is provided with the continuous hole 8 having a ring-like shape symmetric about the center line Cn, and an opening section 8a having a ring-like shape is provided to the upper part of the continuous hole 8 at a position shifted outward from the center line Cn. Further, in the bottom part of the continuous hole 8 at positions shifted toward the center line Cn, there is formed a plurality of gas discharge holes 3a at a predetermined circumferential pitch.

An outer part of the upper surface of the lower plate 6 is bonded to the cut section 7b of the bottom of the upper plate 5, and thus, the opening section 7a of the lower surface of the upper plate 5 and the opening section 8a of the upper surface of the lower plate 6 communicate with each other.

FIG. 1A is a vertical cross-sectional view along the line P-P in the perspective view shown in FIG. 2A, wherein the projection section (hereinafter referred to as the pressing member) 1 projects from the bottom surface of the lower plate 6, and the center of the pressing member 1 coincides with the center line Cn of the lower plate 6. The pressing member 1 is supported by the connection sections 9 respectively extending from the side surfaces, perpendicular to the P-P direction, of the pressing member 1. The pressing member 1 is provided with a suction hole 2a penetrating inside the pressing member 1, and is connected to one of suction devices with a hollow pipe to constitute a suction mechanism 2. The lower surface of the pressing member 1 provided with the suction hole 2a is evenly finished so as to easily adhere to the upper surface of the lid member. The other bottom region than the connection sections 9 for supporting the pressing member 1 is provided with a pair of fume suction holes 4a each having a semicircular shape, which are connected to one of the suction devices with a hollow pipe to constitute a fume suction mechanism 4. The hollow section 7 is connected to the gas feeding device 74 with a hollow pipe to constitute a gas discharge mechanism 3. Specifically, the gas (the inert gas such as a nitrogen gas) supplied from the gas feeding device is then supplied from the discharge holes 3a (the 10 gas discharge holes in the embodiment shown in FIGS. 2A and 2B) bored in the bottom surface of the continuous hole 8 toward the lid member 22 after passing through a channel from the hollow section 7 of the upper plate 5 to the continuous hole 8 of the lower plate 6.

It should be noted that the continuous hole 8 is not required to have a ring-like shape, but can also be a plurality of holes disposed at positions corresponding respectively to the discharge holes 3a.

FIG. 1A shows flows of the gases in the suction mechanism 2, the gas discharge mechanism 3, and the fume suction mechanism 4 with the dotted line A, the dashed-dotted line B, and the dashed-two-dotted line C, respectively. Specifically, when the suction mechanism 2 is made to operate to introduce a negative pressure through the suction hole 2a of the pressing member 1, the flow of the negative pressure indicated by the dotted line A is formed, and thus, the lid member 22 is sucked by the end surface of the pressing member 1. On this occasion, the camera mechanism 72 operates to recognize the suction position of the lid member 22, and thus the control device 76 performs the position adjustment to thereby hold an appropriate position by sucking.

When making the gas discharge mechanism 3 operate, the nitrogen gas fed into the hollow section 7 is discharged from each of the gas discharge holes 3a bored in the bottom plate thereof via the continuous hole 8. Therefore, the nitrogen gas having flowed as indicated by the dashed-dotted line B is supplied from the gas discharge holes 3a toward the lid member 22, and thus, it is possible to fill the cavity of the container 20 with the nitrogen gas to thereby prevent oxidization of a metal portion.

Specifically, since the lid member 22 is in a state of being partially bonded to the base substrate 21 at this point in time, the nitrogen gas is introduced in the container via the gap (a non-bonded region) between the base substrate and the lid member.

When making the fume suction mechanism 4 operate, the gas is suctioned through the fume suction holes 4a shown in FIG. 2A, and the flow of the gas indicated by the dashed-two-dotted line C shown in FIG. 1A is formed. The flow of the gas plays the role of exhausting the metal fine powder, which is generated when laser-bonding the lid member 22 to the sealing section (the bonding area) 21c of the base substrate 21, namely the fumes, to the outside. Further, the flow also plays the role of exhausting a surplus nitrogen gas out of the nitrogen gas, which is supplied through the gas discharge holes 3a, to the outside.

It should be noted that the fume suction holes 4a are also used as an irradiation channel of the energy beam when overlapping the brazing material layer of the lid member 22 with the sealing section (the bonding section) 21c of the base substrate 21, and then partially bonding (temporarily fixing) the peripheral edge of the exterior surface of the lid member 22.

The electronic component container 20 used in the invention is provided with the base substrate 21 using ceramic as the material, and the lid member 22 made of metal, an example of which is shown in the vertical cross-sectional view of FIG. 1B. The base substrate 21 is configured by stacking a lower layer plate 21a using, for example, a ceramics material as the material and having a plate-like shape, and an upper layer plate 21b as an annular body. The lower layer plate 21a forms a bottom section of the base substrate 21, and the upper layer plate 21b as the hollow annular body forms an internal space (a cavity) 28 of the base substrate 21. The ceramic material constituting the lower layer plate 21a and the upper layer plate 21b as ceramic substrates is formed by shaping, processing a ceramic green sheet, and then calcining the ceramic green sheet.

On the upper surface of the lower layer plate 21a in an area near to one end portion, there is formed a plurality of element mounting pads 24 for mounting an electronic element, and the element mounting pads 24 are electrically connected to mounting terminals 25 on the outer bottom surface of the base substrate 21 via a plurality of through holes 26, respectively. An electronic component (a piezoelectric vibrator element) 30 is mounted on the element mounting pads 24 using an electrically-conductive adhesive.

On the peripheral edge of the upper layer plate 21b, there is formed the sealing section (the metalization layer) 21c. An example of the sealing section (the metalization layer) 21c is formed of, for example, a metalization print (e.g., tungsten W), a calcined matter, a nickel (Ni) plate, or a gold (Au) plate. Further, in recent years, there has been developed a method of forming the metalization layer made of, for example, copper (Cu), nickel (Ni), or gold (Au) on a ceramic substrate surface using a semi-additive process. This method is for forming a predetermined metalization layer on a calcined ceramic green sheet using deposition of a metal film (made of copper Cu) using a sputtering process, a photolithography technology, plating (Ni+Au), and an etching process without high-temperature heating. The sealing section (the metalization layer) obtained by the latter process is superior in dimensional accuracy.

Further, the exterior bottom surface of the base substrate 21 is provided with a plurality of mounting terminals 25 to be connected to external wiring.

The element mounting pad 24 and the through hole 26 shown in FIG. 1B are illustrative only, and other wiring examples can also be used. Further, it is desirable to dispose a through hole for electrically connecting the sealing section (the metalization layer) 21c and the mounting terminal 25 for grounding to each other if necessary. In the case of using the container 20 for an electronic device or the like, by keeping the lid member 22 made of metal at the ground potential, protection from an external unwanted electrical signal, for example, noise can be achieved due to the shield effect of the lid member 22, and further, unwanted radiation to the outside can be prevented.

Further, the lid member 22 made of metal is composed of a lid material 22a made of kovar (linear expansion coefficient: 5.5 ppm/° C.), which is a metal material having a linear expansion coefficient approximate to the linear expansion coefficient (7 ppm/° C.) of the ceramic substrates (the lower layer plate 21a, the upper layer plate 21b) constituting the base substrate 21, a brazing material layer 22b stacked on the lower surface of the lid material 22a using a cladding process, for example, silver solder, and a nickel film. 22c for an antioxidant film stacked on the upper surface of the lid material 22a using the cladding process. It should be noted that as the lid material 22a, 42 nickel, SUS, and so on can also be used besides kovar.

FIG. 1B is a partial enlarged vertical cross-sectional view of the bonding jig 60, wherein the brazing material layer 22b of the lid member 22 is arranged so as to overlap the sealing section (the bonding area) 21c of the base substrate 21, and the lid member 22 is held by the pressing member 1 so as not to move due to a mechanical vibration or the like. The distance W1 between the side surface of the pressing member 1 and the inner surface of the upper layer plate 21b as the annular body is in a range of, for example, 100 μm through 200 μm.

Since a predetermined weight due to the pressing member 1 is applied to the central area of the lid member 22, the lid member 22 is bent downward along the direction in which the weight is applied, and it becomes that the sealing section 21c, namely the bonding area 23, and the bonding area of the lid member 22 adhere to each other. It should be noted that in the case of the laser bonding method, the adhesiveness between the sealing section 21c and the lid member 22 is a major requirement for the airtight sealing, and therefore, the measure of applying a predetermined weight to a part of the lid member 22 to thereby bend the lid member 22 toward the cavity 28 is effective. It should be noted that for details, the bonding area 23 is not the entire area of the sealing section 21c, but the area indicated by the symbols 23 in FIG. 1B.

In the state in which the predetermined weight is applied to the center area of the lid member 22 by the pressing member 1, the gas discharge mechanism 3 is made to operate to discharge the nitrogen gas through the gas discharge holes 3a. In the state in which the oxidization of the metal part is prevented, the fume suction mechanism 4 is made to operate and at the same time the energy beam is applied through the fume suction holes 4a to thereby partially bond a predetermined part of the lid member 22. After removing the weight by the pressing member 1, and then detaching the pressing member 1 from the lid member 22, the non-bonded region of the lid member 22 is irradiated with the energy beam to airtightly seal the container 20.

FIG. 4 is a diagram for explaining the laser bonding method of the electronic component container 20, and is a partial enlarged vertical cross-sectional view of the container 20 shown in FIG. 1B. The lid member 22 made of metal is aligned so that the brazing material layer 22b is bonded on the sealing section (the metalization layer) 21c having a ring-like shape of the base substrate 21, and then the peripheral edge of the lid member 22 is irradiated with the energy beam. The irradiation position of the energy beam when bonding the sealing section 21c and the peripheral edge portion of the lid member 22 made of metal to each other is set so that the central portion of the spot diameter of the energy beam roughly coincides with the central portion of the width dimension W2 of the bonding area 23 between the sealing section 21c and the lid member 22 as shown in FIG. 4. An example of the spot diameter of the energy beam is on the order of 100 μm, and an example of the width dimension W2 of the bonding area 23 is on the order of 150 μm. The energy of the energy beam is the maximum at the central portion of the spot diameter, and the amount of energy decreases as the distance from the central portion increases. It should be noted that by setting the central position of the energy beam as described above, the brazing material layer 22b on the reverse surface of the lid member 22 is evenly and surely melted to thereby be developed evenly and in the necessary and sufficient range.

FIG. 5 is a vertical cross-sectional view of the electronic device manufactured by the bonding method of the electronic component container according to the invention using the energy beam, the bonding jig 60, and so on. It is assumed that the deformation amount of the lid member 22 when bending the lid member 22 by applying the weight (e.g., 200 gram-weight through 500 gram-weight) to the pressing material 1 is the deformation amount (e.g., 5 μm through 15 μm), which can absorb the warpage of the base substrate 21 and the lid member 22. In the central portion of the lid member 22, there remains an indentation (shown in FIG. 5 with exaggeration) produced by the pressing member 1.

Although the bonding method using the energy beam in the bonding between the base substrate 21 and the lid member 22 is hereinabove explained, it goes without explaining that this method can also be applied not only to the energy beam but also to the seam welding, the electron beam welding, the ultrasonic bonding, and so on.

According to the bonding method of the electronic component container described above, since the bonding is performed by arranging the base substrate 21 and the lid member 22 so that the bonding area of the lid member 22 overlaps the bonding area (the sealing section) 21c of the base substrate 21, and then irradiating the lid member 22 with the energy beam in the state of making the pressing member 1 have contact with the exterior surface of the area of the lid member 22 surrounded by the bonding area, namely in the state in which the bonding area 23 of the base substrate 21 and the bonding area of the lid member 22 adhere to each other, there is an advantage that the yield of the electronic component container with sufficient airtightness is dramatically improved.

Further, since the bonding method goes through a partial bonding process of partially bonding the lid member 22 by partially irradiating the lid member 22 with the energy beam in the state in which the bonding area 23 of the base substrate 21 and the bonding area of the lid member 22 adhere to each other, and then goes through a full bonding process of releasing the pressing member 1 and then bonding the non-bonded region, there is an advantage that the yield of the electronic component container with sufficient airtightness is dramatically improved.

Further, since the bonding method goes through a full welding process of releasing the pressing member 1, and then seam-welding the non-welded region after partially laser-bonding the lid member 22 in the state in which the bonding area 23 of the base substrate 21 and the bonding area of the lid member 22 adhere to each other, there is an advantage that the yield of the electronic component container with sufficient airtightness is dramatically improved.

Since the laser bonding device is provided with the pressing member 1 for having contact with the exterior surface of the area of the lid member 22 surrounded by the bonding area after arranging the lid member 22 on the bonding area 23 of the base substrate 21 as described above, the suction mechanism 2 for sucking the lid member 22, the gas discharging mechanism 3 for discharging the inert gas to the bonding region between the base substrate 21 and the lid member 22, the fume suction mechanism 4 for suctioning the fumes generated when bonding the base substrate 21 and the lid member 22 to each other, and the laser irradiation device for irradiating the lid member 22 with the energy beam to thereby bond the bonding area of the lid member 22, there is an advantage that the airtightness of the electronic component container is dramatically improved, and at the same time, the inert gas is reduced, and the fumes are prevented from contaminating the inside of the electronic component container and the electronic component.

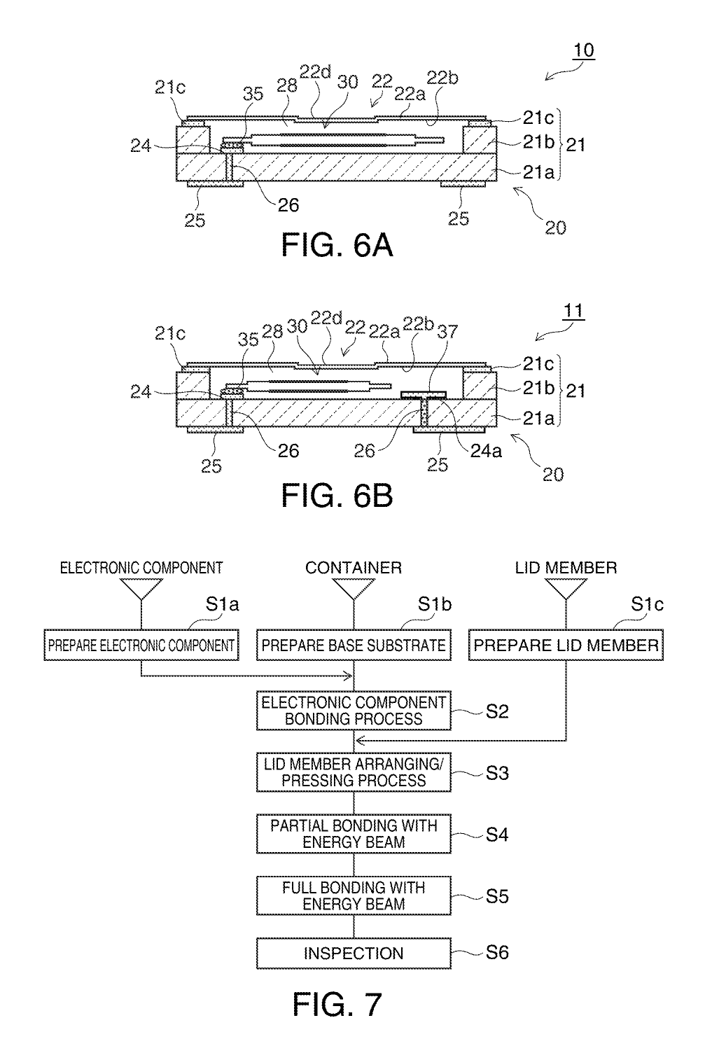

Then, FIG. 6A is a vertical cross-sectional view showing a configuration of a piezoelectric vibrator 10 as an example of the electronic device according to an embodiment using the electronic component container manufactured by the bonding method according to the invention. The electronic device (the piezoelectric vibrator) 10 is provided with an electronic component (a piezoelectric vibrator element) 30 and the container 20 for housing the electronic component 30. The container 20 is provided with the base substrate 21 having recessed section (a cavity) 28, and the lid member 22 made of metal. The brazing material layer 22b is formed on the entire surface of the lid member 22 to be bonded to the base substrate 21. As shown in FIG. 6A, the base substrate 21 is composed of two insulating substrates (a lower layer plate, an upper layer plate), and is formed by calcining a ceramic green sheet made of aluminum oxide as an insulating material. The sealing section 21c as an annular body is formed of a multilayer metalization layer. Further, the bottom of the recessed section (the cavity) 28 is provided with a pair of element mounting pads 24. The plurality of mounting terminals 25 is formed on an exterior bottom surface of the base substrate 21.

The element mounting pads 24 and the mounting terminals 25 of the base substrate 21 are electrically connected to each other via the through holes 26, respectively. The positions of the element mounting pads 24 are arranged so as to correspond respectively to pad electrodes of the electronic component (the piezoelectric vibrator element) 30 when mounting the electronic component (the piezoelectric vibrator element) 30.

The electronic component (the piezoelectric vibrator element) 30 as an example of the electronic device is roughly provided with a quartz crystal substrate, a pair of excitation electrodes, lead electrodes, and electrode pads. In the case of an AT-cut quartz crystal vibrator element, it is common to adopt a mesa structure in the quartz crystal substrate in order to achieve miniaturization. The quartz crystal substrate having the mesa structure makes it possible to achieve mass fabrication of the quartz crystal substrate with the same quality by applying a photolithography process and an etching process to a large quartz crystal wafer. The mesa structure of the quartz crystal substrate can be a single layer structure symmetrical in the thickness direction, a double layer structure, or a triple layer structure depending on the required characteristics of the quartz crystal vibrator.

The excitation electrodes are formed in the roughly center portion of the quartz crystal substrate, and form lead electrodes respectively extending toward the electrode pads formed in an end portion of the quartz crystal substrate. In an example, the excitation electrodes are formed by stacking a gold (Au) electrode film on a foundation of an electrode film made of chrome (Cr) or nickel (Ni) using a sputtering process, a vacuum evaporation process, and so on to form the quartz crystal substrate, and then shaping the electrode films into predetermined shapes using the photolithography process. By using this process, it is possible to form the excitation electrodes, the lead electrodes, and the electrode pads at a time in predetermined shapes. The size of the excitation electrodes may extend to a part of a vertex portion or the peripheral edge of the mesa structure depending on the required specifications. Further it is common that the size of the excitation electrodes is determined so as to suppress a high-order bending mode.

When fixing the electronic component (the piezoelectric vibrator element) 30 to the base substrate 21, the electrically-conductive adhesive 35 is first applied to the element mounting pads 24, then the electronic component (the piezoelectric vibrator element) 30 is mounted so that the pad electrodes are aligned to the element mounting pads 24, and then a predetermined weight is applied thereon. Although as the electrically-conductive adhesive 35, there can be cited a silicone adhesive, an epoxy adhesive, a polyimide adhesive, and so on, it is preferable to select an adhesive weak in strength of stress (proportional to distortion) due to the adhesive 35 and small in amount of outgas taking aging into consideration.

In order to cure the electrically conductive adhesive 35 of the piezoelectric vibrator element 30 mounted on the base substrate 21, the base substrate 21 and the piezoelectric vibrator element 30 are put in a high-temperature oven at predetermined temperature for a predetermined time period. After curing the electrically-conductive adhesive 35 and then performing an annealing treatment thereon, frequency adjustment is performed by adding or removing amass to or from the excitation electrodes. The lid member 22 is arranged on the sealing section 21c formed on the upper surface of the base substrate 21, and then the brazing material layer 22b of the lid member 22 and the sealing section 21c are laser-bonded to each other to complete the seal in the chamber of the laser bonding device while discharging the N₂ gas, and thus the piezoelectric vibrator 10 is completed.

By configuring the electronic device, for example, the piezoelectric vibrator 10 as shown in FIG. 6A, since the yield of the container 20 with the sufficient airtightness is improved, there is an advantage that it is possible to configure a piezoelectric device superior in frequency accuracy, frequency-temperature characteristic, and aging.

FIG. 6B is a vertical cross-sectional view showing an electronic device 11 according to another embodiment of the invention. An example of the electronic device 11 is roughly provided with the electronic component (e.g., the piezoelectric vibrator element) 30, at least one second electronic component (e.g., an IC) 37, the container 20 for housing these components, and the lid member 22. On the bottom surface of the cavity 28 of the base substrate 21, there are disposed the element mounting pads 24 and component mounting pads 24a, both of which are electrically connected to the mounting terminals 25 via the through holes 26, respectively. The element mounting pads 24 are coated with the electrically-conductive adhesive 35, the pad electrodes of the electronic component (the piezoelectric vibrator element) 30 are mounted thereon, a predetermined weight is applied thereon, and then a heat treatment is performed in order to cure the electrically-conductive adhesive 35. Further, the second electronic component 37 is mounted on the component mounting pads 24a, and is then bonded using a measure such as ultrasonic bonding. The lid member 22 is arranged so as to be fit to the sealing section 21c on the upper surface of the base substrate 21, the base substrate 21 and the lid member 22 are input into the chamber of the laser bonding device and then laser-bonded to each other, and thus, the electronic device 11 is completed. The container 20 of the electronic device 11 is filled with a nitrogen gas (N₂).

In the example of the embodiment described above, it is desirable to configure the electronic device using at least one of a thermistor, a capacitor, a reactance element, and a semiconductor element (e.g., an IC provided with a variable-capacitance diode, an oscillator circuit, an amplifier, and so on) as the second electronic component 37 to be housed in the container 20.

FIG. 7 is an overview flowchart showing an example of a method of manufacturing the electronic device 10 according to the invention. There are provided a process (S1a) for preparing the electronic component 30, a process (S1b) for preparing the base substrate 21, and a process (S1c) for preparing the lid member 22. There are further provided an electronic element bonding process (S2) for applying the electrically-conductive adhesive 35 to the element mounting pads 24 formed on the bottom portion of the cavity 28 of the base substrate 21, then arranging the pad electrodes of the electronic component 30 on the electrically-conductive adhesive 35, and then drying the electrically-conductive adhesive 35, a lid member arranging/pressing process (S3) for arranging the lid member 22 so as to overlap the bonding area 23 of the sealing section 21c of the base substrate 21, and then pressing the area of the lid member 22 surrounded by the bonding area with the pressing member 1, and at the same time making the gas discharge mechanism 3 operate to supply the nitrogen gas, a partial bonding process (S4) for making the fume suction mechanism 4 and the laser irradiation device operate to apply the energy beam through the fume suction holes 4a to thereby temporarily fixing a part of the lid member 22, a process (S5) for detaching the pressing member 1 from the lid member 22, and then irradiating the non-bonded region with the energy beam on the peripheral edge of the lid member 22 to thereby fully bond the lid member 22, and an inspection process (S6).

The electronic device 11 shown in FIG. 6B can also be manufactured in an equivalent procedure.

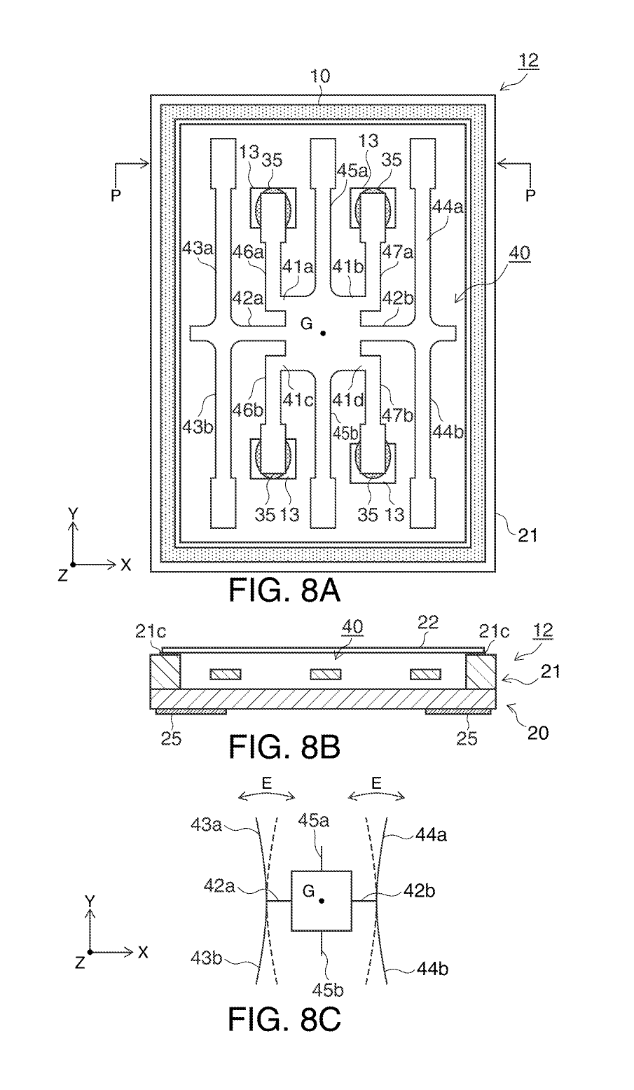

FIG. 8A is a schematic plan view of a gyro sensor 12 configured using the container 20 according to the invention, wherein the lid member 22 is removed from the drawing. FIG. 8B is a cross-sectional view along the line P-P shown in FIG. 8A. The vibration gyro sensor 12 is roughly provided with a vibration gyro element 40, and the container 20 for housing the vibration gyro element 40. The container 20 is provided with the base substrate 21, and the lid member 22 for airtightly sealing the cavity 28 of the base substrate 21.

The vibration gyro element 40 is provided with a base section 41, and a pair of detecting vibrating arms 45a, 45b disposed so as to project on the same straight line respectively from two ends of the base section 41 opposed to each other. Further, the vibration gyro element 40 is provided with a pair of first connection arms 42a, 42b disposed so as to project on the same straight line in a direction perpendicular to the detecting vibrating arms 45a, 45b respectively from the other two ends of the base section 41 opposed to each other, a pair of driving vibrating arms 43a, 43b disposed so as to project in both directions perpendicular to the first connection arm 42a respectively from a tip portion of the first connection arm 42a, and a pair of driving vibrating arms 44a, 44b disposed so as to project in both directions perpendicular to the first connection arm 42b respectively from a tip portion of the first connection arm 42b.

The vibration gyro element 40 is further provided with a pair of second connection arms 41a, 41b disposed so as to project on the same straight line in a direction perpendicular to the detecting vibrating arms 45a, 45b respectively from the other two ends of the base section 41 opposed to each other, a pair of second connection arms 41c, 41d disposed so as to project on the same straight line in a direction perpendicular to the detecting vibrating arms 45a, 45b respectively from the other two ends of the base section 41 opposed to each other, a pair of support arms 46a, 46b disposed between the detecting vibrating arms 45a, 45b and the driving vibrating arms 43a, 43b so as to project in both directions perpendicular to the second connection arms 41a, 41c from tip portions of the second connection arms 41a, 41c, respectively, and a pair of support arms 47a, 47b disposed between the detecting vibrating arms 45a, 45b and the driving vibrating arms 44a, 44b so as to project in both directions perpendicular to the second connection arms 41b, 41d from tip portions of the second connection arms 41b, 41d, respectively.

The excitation electrodes are respectively provided at least to the pair of detecting vibrating arms 45a, 45b, and the pairs of driving vibrating arms 43a, 43b, and 44a, 44b. The support arms 46a, 46b, and 47a, 47b are provided with a plurality of electrode pads (not shown), and the electrode pads and the excitation electrodes are electrically connected to each other, respectively.

The vibration gyro sensor 12 is provided with buffers made of metal or a polymer material disposed on the inside surface of the base substrate 21 at regions opposed to the tip portions of the detecting vibrating arms 45a, 45b, and the driving vibrating arms 43a, 43b, and 44a, 44b of the vibration gyro element 40.

FIG. 8C is a schematic plan view for explaining an operation of the vibration gyro element. In the state in which no angular velocity is applied to the vibration gyro sensor 12, the driving vibrating arms 43a, 43b, 44a, 44b perform a flexural vibration in a direction indicated by the arrows E. On this occasion, since the driving vibrating arms 43a, 43b, and 44a, 44b perform the vibration symmetric about the straight line in the Y-axis direction passing through the centroid G, the base section 41, the connection arms 42a, 42b, and the detecting vibrating arms 45a, 45b hardly vibrate.

When an angular velocity ω around the Z axis is applied to the vibration gyro sensor 12, a Coriolis force acts on the driving vibrating arms 43a, 43b, 44a, 44b and the first connection arms 42a, 42b, and a new vibration is excited. This vibration is a vibration in a circumferential direction with respect to the centroid G. At the same time, in the detecting vibrating arms 45a, 45b, there is excited a detection vibration in accordance with this vibration. The distortion generated by this vibration is detected by the detection electrodes provided to the detecting vibrating arms 45a, 45b, and thus, the angular velocity is obtained.

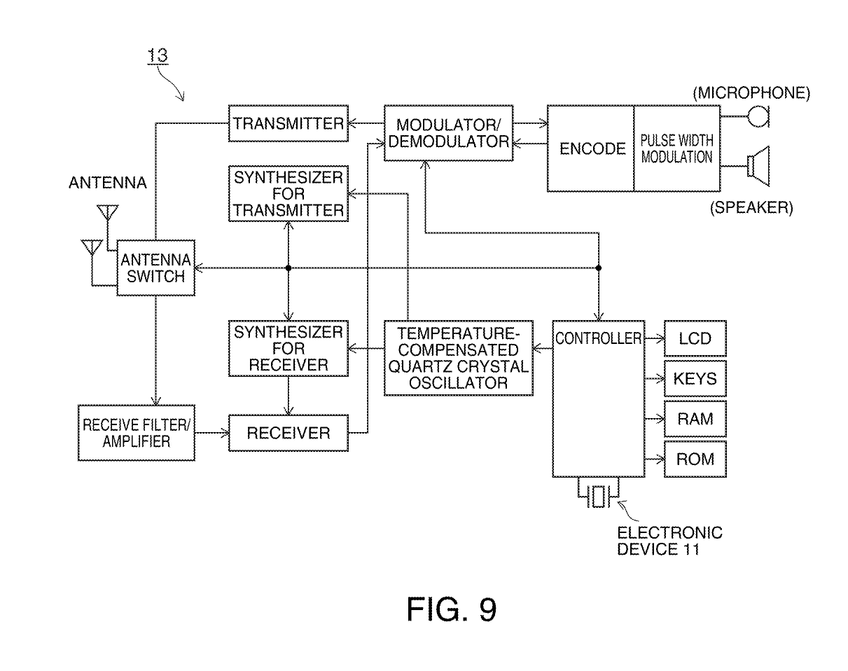

FIG. 9 is a general block diagram showing a configuration of a digital cellular phone 13 using at least one of the electronic devices 10, 11 shown in FIGS. 6A and 6B. The explanation will be presented using the electronic device (e.g., the piezoelectric device) 11 as an example. In the case of transmitting a voice by the digital cellular phone 13 shown in FIG. 9, when the user inputs his or her voice to a microphone, the signal passes through a circuit for pulse width modulation/coding, and a circuit of modulator/demodulator, and is then transmitted from the antenna via a transmitter and an antenna switch. On the other hand, the signal transmitted from the other end of the line is received by the antenna, and then enters the receiver circuit through the antenna switch, a receive filter/amplifier circuit, and then input to the modulator/demodulator circuit from the receiver circuit. Further, it is arranged that the signal demodulated by the demodulator circuit passes through the pulse width modulation/coding circuit, and is then output from the speaker as a voice. A controller is provided in order to control the antenna switch, the modulator/demodulator circuit, and so on.

Since the controller also controls an LCD as a display section, keys as an input section for numeric characters and so on, and further a RAM, a ROM, and so on besides the function described above, the frequency of the piezoelectric device used is required to be high in accuracy and high in stability. The electronic device meeting this requirement is the piezoelectric device 11 shown in FIG. 6B.

In the case of configuring an electronic apparatus using the electronic device using the electronic component container manufactured using the bonding method according to the invention as described above, since the electronic apparatus 13 is configured using the electronic device 11 good in frequency accuracy, frequency-temperature characteristic, and aging characteristic, there is an advantage that the electronic apparatus 13 stable in frequency for a long period of time can be obtained.

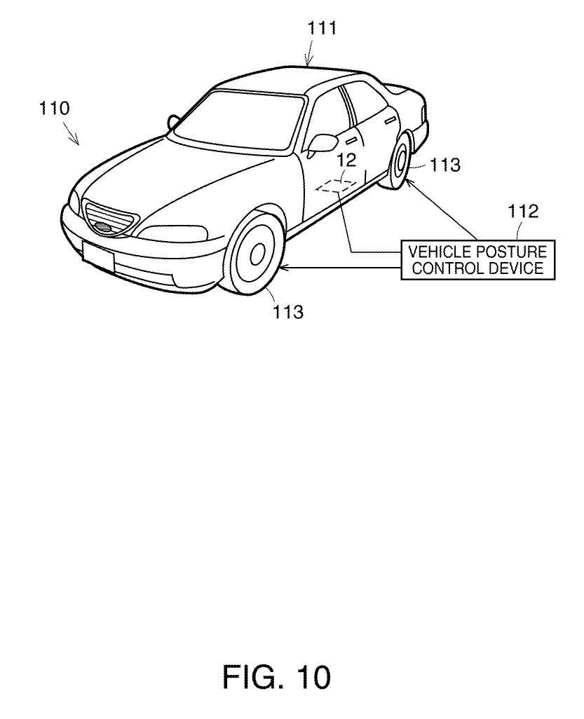

FIG. 10 schematically shows a vehicle 110 equipped with an apparatus for a moving object as a specific example. The vehicle 110 incorporates the gyro sensor 12 having the gyro element 40 as shown in, for example, FIGS. 8A through 8C. The gyro sensor 12 can detect the posture of the vehicle body 111. The detection signal of the gyro sensor 12 can be supplied to a vehicle posture control device 112. The vehicle posture control device 112 is capable of, for example, controlling the stiffness of the suspension, and controlling the brake of each of the wheels 113 in accordance with the posture of the vehicle body 111. Besides the above, such posture control as described above can be used for a two-legged robot and a radio control helicopter. In realizing the posture control, the gyro sensor 12 is incorporated.

Since the apparatus for a moving object is configured using such an electronic device small in size, stable in output, and good in aging characteristic as described above, there is an advantage of achieving downsizing of the apparatus for a moving object, and obtaining the apparatus for a moving object stable for a long period of time.

The entire disclosure of Japanese Patent Application No. 2012-233498, filed Oct. 23, 2012 is expressly incorporated by reference herein.

What is claimed is:

1. A method of manufacturing an electronic device comprising:
providing an electronic component, a lid member, a base substrate having a bonding area, and a pressing member;
arranging the electronic component above the base substrate;
arranging the lid member above the base substrate so as to overlap the bonding area of the base substrate;
making the pressing member have contact with an area of the lid member surrounded by the bonding area in a plan view in a direction in which the base substrate and the lid member overlap each other; and
bonding the base substrate and the lid member to each other by irradiating the lid member with an energy beam in a state of making the pressing member have contact with the lid member.

2. The method of manufacturing an electronic device according to claim 1, wherein
a part of the bonding area is bonded in the bonding of the base substrate and the lid member, and
the method further comprises:
detaching the pressing member from the lid member after the bonding of the base substrate and the lid member; and
bonding a remaining area of the bonding area.

3. The method of manufacturing an electronic device according to claim 2, wherein
seam welding is used in the bonding of a remaining area.

4. A bonding device adapted to bond a base substrate and a lid member to each other to assemble an electronic component container, the bonding device comprising:
a pressing member adapted to fix the lid member to the base substrate; and
an energy beam irradiation device adapted to irradiated the lid member with an energy beam to bond the base substrate and the lid member to each other.

5. The bonding device according to claim 4, wherein
the pressing member includes a suction mechanism adapted to suck and transport the lid member.

6. The bonding device according to claim 4, wherein
the pressing member includes a mechanism adapted to discharge a gas, and a mechanism adapted to suction a gas.

7. An electronic device manufactured by a method comprising:
providing an electronic component, a lid member, a base substrate having a bonding area, and a pressing member;
arranging the electronic component above the base substrate;
arranging the lid member above the base substrate so as to overlap the bonding area of the base substrate;
making the pressing member have contact with an area of the lid member surrounded by the bonding area in a plan view in a direction in which the base substrate and the lid member overlap each other; and
bonding the base substrate and the lid member to each other by irradiating the lid member with an energy beam in a state of making the pressing member have contact with the lid member.

8. An electronic apparatus comprising:
an electronic device according to claim 7.

9. A apparatus for a moving object comprising:
an electronic device according to claim 7.
